(19) United States
(12) Patent Application Publication
(10) Pub. No.: US 2023/0343770 A1
(43) Pub. Date: Oct. 26, 2023

(54) SEMICONDUCTOR MODULE

(71) Applicant: FUJI ELECTRIC CO., LTD., Kawasaki-shi (JP)

(72) Inventor: Nobuharu KUSAKARI, Matsumoto-city (JP)

(73) Assignee: FUJI ELECTRIC CO., LTD., Kawasaki-shi (JP)

(21) Appl. No.: 18/172,561

(22) Filed: Feb. 22, 2023

(30) Foreign Application Priority Data
Apr. 25, 2022 (JP) 2022-071385

(51) Int. Cl. H01L 25/00; H01H 85/02; H01L 23/31; H01L 23/00; H01L 25/18; H01L 23/29

(52) U.S. Cl. CPC H01L 25/18; H01H 85/0241; H01L 23/296; H01L 23/3135; H01L 24/45; H01L 24/48; H01L 25/50; H01H 2085/0283; H01L 24/32; H01L 24/73; H01L 2224/32227; H01L 2224/45124; H01L 2224/45147; H01L 2224/48091; H01L 2224/48106; H01L 2224/48139; H01L 2224/48155; H01L 2224/73265; H01L 2924/1715; H01L 2924/1811; H01L 2924/186

(57) ABSTRACT

A semiconductor module includes a mounting substrate, a transistor mounted on the mounting substrate, a housing configured to house a semiconductor element, a first sealing layer filled in a space inside the housing to seal the transistor, a second sealing layer of a resin material softer than the first sealing layer and layered on the first sealing layer, and a wire electrically connected to the transistor, in which the wire includes a first portion covered with the first sealing layer and a second portion covered with the second sealing layer.

### CROSS REFERENCE TO RELATED APPLICATIONS

This application is based on, and claims priority from, Japanese Patent Application No. 2022-071385, filed on Apr. 25, 2022, the entire content of which is incorporated herein by reference.

### BACKGROUND OF THE INVENTION

### Field of the Invention

The present disclosure relates to a semiconductor module.

### Description of Related Art

For example, a semiconductor module using a power semiconductor element, such as an insulated gate bipolar transistor (IGBT) or a metal-oxide-semiconductor field-effect transistor (MOSFET), has been conventionally proposed. For example, Japanese Patent Application Laid-Open Publication No. 2022-53848 and Japanese Patent Application Laid-Open Publication No. 2013-258321 each disclose a semiconductor device including a semiconductor element mounted on a circuit substrate, and a case configured to house the semiconductor element. The semiconductor element is connected to an external connection terminal by a bonding wire. The semiconductor element and the bonding wire are sealed with a sealing resin filled in a space inside the case.

In response to occurrence of an abnormality such as a short circuit in a semiconductor element, an overcurrent is continuously supplied to the wiring member (hereinafter, referred to as an “abnormal state”). In order to cut off an overcurrent in such an abnormal state, it is necessary to externally connect a fuse to the semiconductor module.

### SUMMARY OF THE INVENTION

In view of the above-described circumstances, an object of one aspect of the present disclosure is to provide a semiconductor module incorporating a function of cutting off an overcurrent in an abnormal state.

In order to achieve the above-described object, a semiconductor module according to the present disclosure includes: a mounting substrate; a semiconductor element mounted on the mounting substrate; a housing configured to house the semiconductor element; a first sealing layer filled in a space inside the housing to seal the semiconductor element; a second sealing layer of a resin material softer than the first sealing layer and layered on the first sealing layer; and a wiring member electrically connected to the semiconductor element, in which the wiring member includes: a first portion covered with the first sealing layer; and a second portion covered with the second sealing layer.

### BRIEF DESCRIPTION OF THE DRAWINGS

FIG. 1 is a plan view illustrating a configuration of a semiconductor module according to a first embodiment;

FIG. 2 is a cross-sectional view taken along line II-II in FIG. 1;

FIG. 3 is an enlarged cross-sectional view of the vicinity of a wire;

FIG. 4 is a process chart illustrating a manufacturing process of the semiconductor module;

FIG. 5 is a cross-sectional view of the semiconductor module in the process of manufacturing;

FIG. 6 is a cross-sectional view of a semiconductor module according to a second embodiment;

FIG. 7 is a cross-sectional view of the vicinity of a wire in a modification;

FIG. 8 is a cross-sectional view of the vicinity of a wire in a modification;

FIG. 9 is a cross-sectional view of the vicinity of a wire in a modification; and

FIG. 10 is a cross-sectional view of a semiconductor module according to a modification.

### DESCRIPTION OF THE EMBODIMENTS

Embodiments for carrying out the present disclosure will be described with reference to the drawings. In each drawing, dimensions and scales of each element may be different from those of an actual product. In addition, the embodiments described below are exemplary embodiments assumed when the present disclosure is implemented. Therefore, the scope of the present disclosure is not limited to the following exemplary embodiments.

### A: First Embodiment

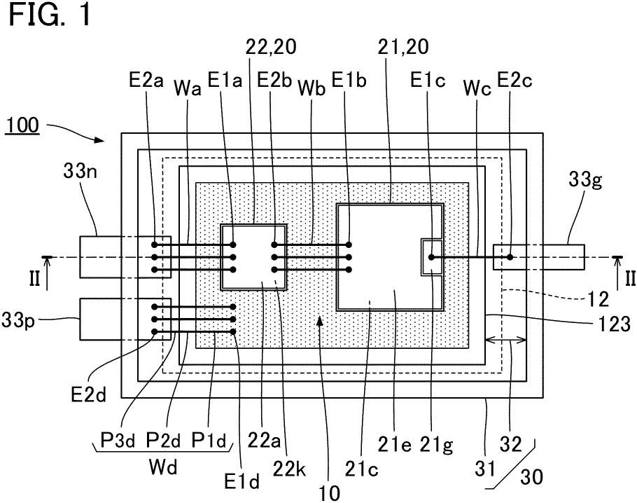

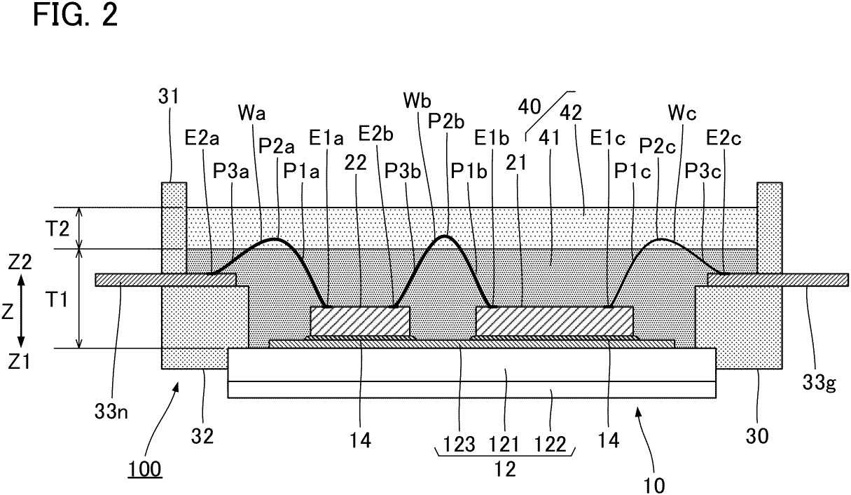

FIG. 1 is a plan view illustrating a configuration of a semiconductor module 100. FIG. 2 is a cross-sectional view taken along line II-II in FIG. 1. For example, the semiconductor module 100 of the first embodiment is a power semiconductor device that comprises an inverter circuit that drives an electric motor such as a three-phase motor.

In the following description, a Z axis is assumed as illustrated in FIG. 2. One direction along the Z axis is referred to as a Z1 direction, and a direction opposite to the Z1 direction is referred to as a Z2 direction. In an actual state of use, the semiconductor module 100 can be mounted in any direction, but in the following description, the Z1 direction is assumed to be downward and the Z2 direction is assumed to be upward for convenience. Therefore, a surface of any element of the semiconductor module 100 facing the Z1 direction may be referred to as a “lower surface”, and a surface of the element facing the Z2 direction may be referred to as an “upper surface”.

As illustrated in FIGS. 1 and 2, the semiconductor module 100 includes a semiconductor unit 10, a housing 30, and a sealing member 40. In FIG. 1, the sealing member 40 is not shown for convenience.

The housing 30 is a case that houses and supports the semiconductor unit 10 and the sealing member 40. The housing 30 of the first embodiment includes a side wall 31 having a rectangular frame shape and a projection 32 projecting from an inner wall surface of the side wall 31. For example, the housing 30 may be formed from various insulating resins such as a polyphenylene sulfide (PPS) resin, a polybutylene terephthalate (PBT) resin, a polybutylene succinate (PBS) resin, a polyamide (PA) resin, and an acrylonitrile-butadiene-styrene (ABS) resin.

A plurality of connection terminals 33 (33n, 33p, 33g) is housed in the housing 30. Each of the connection terminals 33 is formed as a single body with the housing 30 by, for example, insert molding. Each connection terminal 33 extends in a direction intersecting the Z axis, passing through the side wall 31. Each connection terminal 33 has a portion located inside the side wall 31, and this portion is disposed on the upper surface of the projection 32.

The connection terminals 33 include a connection terminal 33n, a connection terminal 33p, and a connection terminal 33g. To the connection terminal 33n, a power supply voltage on the lower potential side is supplied from an external power supply, and to the connection terminal 33p, a power supply voltage on the higher potential side is supplied from an external power supply. To the connection terminal 33g, a control voltage for controlling the semiconductor module 100 is supplied from an external control device.

The semiconductor unit 10 includes a mounting substrate 12, a transistor 21, and a diode 22. The mounting substrate 12 is a rectangular plate-like member that supports the transistor 21 and the diode 22. For example, a substrate, such as a direct copper bonding (DCB) substrate, an active metal brazing (AMB) substrate, or an insulated metal substrate (IMS), is used as the mounting substrate 12.

As illustrated in FIG. 2, the mounting substrate 12 is mounted to the housing 30. Specifically, the mounting substrate 12 is fixed to the projection 32 using, for example, a bonding material such as an adhesive. The mounting substrate 12 is a multilayer substrate including layers of an insulating plate 121, a metal plate 122, and a conductor pattern 123. The insulating plate 121 is a rectangular plate-like member formed from an insulating material. The insulating substrate is formed from, for example, a ceramic material such as aluminum oxide, aluminum nitride, or silicon nitride, or a resin material such as an epoxy resin. The metal plate 122 is a rectangular plate-like member bonded to the lower surface of the insulating plate 121 facing the Z1 direction. The metal plate 122 is formed from, for example, a metal material having a high thermal conductivity such as copper or aluminum, and functions as a heat sink that transmits heat generated in the semiconductor module 100 to the outside. The conductor pattern 123 is a conductive film formed on the upper surface of the insulating plate 121 facing the Z2 direction. The conductor pattern 123 is formed from, for example, a low-resistance conductive material such as copper or a copper alloy.

The transistor 21 and the diode 22 are semiconductor elements mounted on the mounting substrate 12. As illustrated in FIG. 2, the transistor 21 and the diode 22 are accommodated in a space inside the housing 30. More specifically, the transistor 21 and the diode 22 are surrounded by the projection 32. The upper surface of the transistor 21 and the upper surface of the diode 22 are lower than (that is, in the Z1 direction from) the upper surface of the projection 32. Although only one set of the transistor 21 and the diode 22 is illustrated for convenience in the first embodiment, a plurality of sets of the transistor 21 and the diode 22 may be mounted on the mounting substrate 12. It is to be noted that, in the following description, the transistor 21 and the diode 22 each may be referred to as a “semiconductor element 20”. One of the transistor 21 and the diode 22 is an example of a “first semiconductor element”, and the other of the transistor 21 and the diode 22 is an example of a “second semiconductor element”.

The transistor 21 is a power semiconductor element capable of switching conduction and cutting off a current. The transistor 21 of the first embodiment is an insulated gate bipolar transistor (IGBT). As illustrated in FIG. 1, the transistor 21 includes a semiconductor chip including an electrode 21e, an electrode 21c, and a control electrode 21g. The electrode 21e and the electrode 21c are main electrodes to which a current to be controlled is input or output. Specifically, the electrode 21e is an emitter electrode formed on the upper surface of the transistor 21, and the electrode 21c is a collector electrode formed on the lower surface of the transistor 21. On the other hand, the control electrode 21g is a gate electrode to which a control voltage for controlling the turning on and off of the transistor 21 is applied, and is formed on the upper surface of the transistor 21 together with the electrode 21e.

The diode 22 is a power semiconductor element that rectifies a current. The diode 22 includes a semiconductor chip including an anode 22a and a cathode 22k. The anode 22a is formed on the upper surface of the diode 22, and the cathode 22k is formed on the lower surface of the diode 22.

As illustrated in FIG. 2, each semiconductor element 20 is bonded to the mounting substrate 12 via, for example, a bonding material 14 such as solder. Specifically, the electrode 21c of the transistor 21 and the cathode 22k of the diode 22 are bonded to the conductor pattern 123 with the bonding material 14. That is, the bonding material 14 is interposed between each semiconductor element 20 and the conductor pattern 123.

Multiple wires W (Wa, Wb, Wc, and Wd) are connected to the semiconductor unit 10. A wire W is a wiring member electrically connected to the semiconductor elements 20. Specifically, each wire W is a linear bonding wire formed from, for example, a low-resistance conductive material such as copper or aluminum. The wires W include multiple wires Wa, multiple wires Wb, one wire Wc, and multiple wires Wd.

A wire Wa is a wiring member that electrically connects the connection terminal 33n and the diode 22 (and then the transistor 21). The wire Wa includes a first end E1a and a second end E2a located at opposite ends. The first end E1a is bonded to the anode 22a of the diode 22, and the second end E2a is bonded to the connection terminal 33n. As illustrated in FIG. 2, each wire Wa is curved in an arc shape or is bent at an angle in the shape of a polygonal line, protruding in the Z2 direction between the diode 22 and the connection terminal 33n. The number of wires Wa may be freely selected. For example, only one wire Wa may be provided between the connection terminal 33n and the diode 22.

A wire Wb is a wiring member that electrically connects the transistor 21 and the diode 22. The wire Wb includes a first end E1b and a second end E2b located at opposite ends. The first end E1b is bonded to the electrode 21e of the transistor 21, and the second end E2b is bonded to the anode 22a of the diode 22. As illustrated in FIG. 2, each wire Wb is curved in an arc shape or is bent at an angle in the shape of a polygonal line, shape protruding in the Z2 direction between the transistor 21 and the diode 22. The number of wires Wb may be freely selected. For example, only one wire Wb may be provided between the transistor 21 and the diode 22. The wires Wb are examples of a “second wiring member”.

The wire Wc is a wiring member that electrically connects the connection terminal 33g and the transistor 21. The wire Wc is a conductor thinner than the other wires W (Wa, Wb, and Wd). The wire Wc includes a first end E1c and a second end E2c located at opposite ends. The first end E1c is bonded to the control electrode 21g of the transistor 21, and the second end E2c is bonded to the connection terminal 33g. As illustrated in FIG. 2, the wire Wc is curved in an arc shape or is bent at an angle in the shape of a polygonal line, protruding in the Z2 direction between the connection terminal 33g and the transistor 21. The number of wires Wc may be freely selected. For example, multiple wires Wc may be provided between the connection terminal 33g and the transistor 21. The wires Wa and the wire Wc are examples of “first wiring members”.

As illustrated in FIG. 1, the wires Wd are wiring members that electrically connect the connection terminal 33p and the conductor pattern 123. A wire Wd includes a first end E1d and a second end E2d located at opposite ends. The first end E1d is bonded to the conductor pattern 123, and the second end E2d is bonded to the connection terminal 33p. The wire Wd is curved in an arc shape or is bent at an angle in the shape of a polygonal line, protruding in the Z2 direction between the connection terminal 33p and the conductor pattern 123. The number of wires Wd may be freely selected. For example, only one wire Wd may be provided between the connection terminal 33p and the conductor pattern 123.

The sealing member 40 in FIG. 2 is an insulator that seals the semiconductor unit 10, with a space inside the housing 30 filled therewith. Specifically, the sealing member 40 is formed in a space surrounded by the housing 30, with the mounting substrate 12 constituting a bottom of the space. The sealing member 40 is formed of layers of a first sealing layer 41 and a second sealing layer 42. The space inside the housing 30 is filled with the first sealing layer 41 and the second sealing layer 42. The second sealing layer 42 is layered on the first sealing layer 41. That is, the first sealing layer 41 is interposed between the mounting substrate 12 and the second sealing layer 42. In other words, the second sealing layer 42 covers the first sealing layer 41. The interface between the first sealing layer 41 and the second sealing layer 42 is a flat plane perpendicular to the Z axis.

The first sealing layer 41 seals the semiconductor elements 20. Specifically, the first sealing layer 41 is in contact with the outer surfaces (upper surfaces and side surfaces) of the transistor 21 and the diode 22, the surface of the bonding material 14, and the surface of the mounting substrate 12. The second sealing layer 42 seals the wires W and the first sealing layer 41. The upper surface of the second sealing layer 42 is at a position higher than (that is, in the Z2 direction from) the highest point of each wire W. That is, the wires W are entirely sealed by the sealing member 40.

A thickness T1 of the first sealing layer 41 is greater than a thickness T2 of the second sealing layer 42 (T1 > T2). The thickness T1 of the first sealing layer 41 corresponds to a distance between the surface of mounting substrate 12 (specifically, the insulating plate 121) and the upper surface of the first sealing layer 41. The thickness T2 of the second sealing layer 42 corresponds to a distance between the lower surface and the upper surface of the second sealing layer 42. The upper surface of the first sealing layer 41 is at a position higher than (that is, in the Z2 direction from) the upper surface of the connection terminals 33 (33n, 33p, and 33g). That is, the upper surfaces of the connection terminals 33 are covered with the first sealing layer 41 and are not in contact with the second sealing layer 42.

The first sealing layer 41 and the second sealing layer 42 are formed from different insulating materials. The first sealing layer 41 is formed from, for example, a relatively hard resin material, such as an epoxy resin or an acrylic resin. Note that the material of the first sealing layer 41 is not limited to the above-described examples. Various fillers of, for example, silicon oxide or aluminum oxide, may be contained in the first sealing layer 41.

On the other hand, the second sealing layer 42 is formed from a resin material softer than the first sealing layer 41. In other words, the elastic modulus of the second sealing layer 42 is less than the elastic modulus of the first sealing layer 41. For example, the second sealing layer 42 is formed from a silicone gel. It is to be noted that the material of the second sealing layer 42 is not limited to the above-described example. For example, the second sealing layer 42 may be formed from a resin material softer than the first sealing layer 41 such as a rubber (for example, silicone rubber). Various fillers of, for example, silicon oxide or aluminum oxide may be contained in the second sealing layer 42.

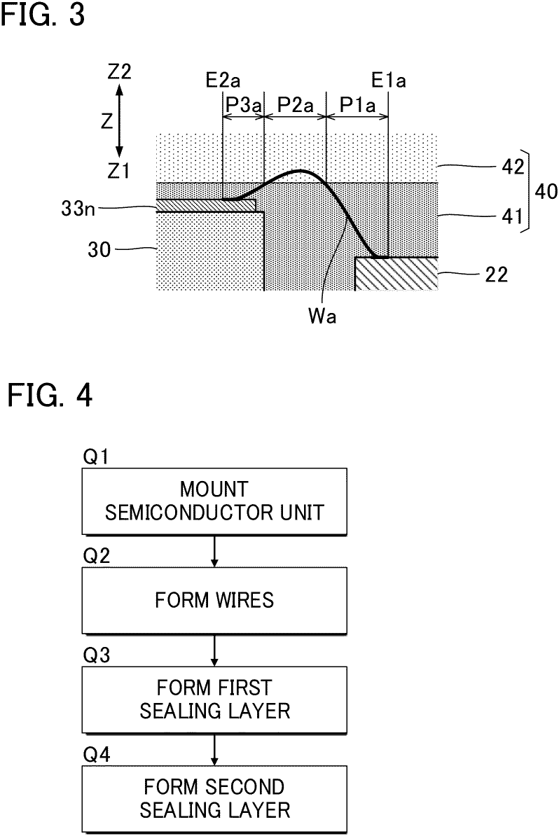

FIG. 3 is a cross-sectional view focusing on the relationship between the sealing member 40 and the respective wire Wa. As illustrated in FIG. 3, the wire Wa is formed across both the first sealing layer 41 and the second sealing layer 42.

The wire Wa includes a first portion P1a, a second portion P2a, and a third portion P3a. The first portion P1a is a portion including the first end E1a. The third portion P3a is a portion including the second end E2a. The second portion P2a is a portion between the first portion P1a and the third portion P3a. The second portion P2a is at a position higher than (that is, in the Z2 direction from) the first portion P1a and the third portion P3a.

As illustrated in FIG. 3, the first portion P1a and the third portion P3a are covered with the first sealing layer 41. Specifically, the first portion P1a and the third portion P3a are in contact with the first sealing layer 41 over the entire circumference. On the other hand, the second portion P2a is covered with the second sealing layer 42. Specifically, the second portion P2a is in contact with the second sealing layer 42 over the entire circumference. As will be understood from the above description, the first portion P1a and the third portion P3a of the wire Wa are sealed by the first sealing layer 41, and the second portion P2a of the wire Wa is exposed from the first sealing layer 41.

The same applies to the relationship between the sealing member 40 and the other wires W (Wb, Wc, and Wd). For example, as illustrated in FIG. 2, each of the wires Wb includes a first portion P1b including the first end E1b, a third portion P3b including the second end E2b, and a second portion P2b between the first portion P1b and the third portion P3b. The first portion P1b and the third portion P3b are covered with the first sealing layer 41, and the second portion P2b is covered with the second sealing layer 42.

The wire Wc includes a first portion P1c including the first end E1c, a third portion P3c including the second end E2c, and a second portion P2c between the first portion P1c and the third portion P3c. The first portion P1c and the third portion P3c are covered with the first sealing layer 41, and the second portion P2c is covered with the second sealing layer 42.

As illustrated in FIG. 1, each of the wires Wd similarly includes a first portion P1d including the first end E1d, a third portion P3d including the second end E2d, and a second portion P2d between the first portion P1d and the third portion P3d. The first portion P1d and the third portion P3d are covered with the first sealing layer 41, and the second portion P2d is covered with the second sealing layer 42.

As will be understood from the above description, each of the wires W (Wa, Wb, Wc, and Wd) includes:
(1) a first portion P1 (P1a, P1b, P1c, or P1d) covered with the first sealing layer 41;
(2) a second portion P2 (P2a, P2b, P2c, or P2d) covered with the second sealing layer 42; and
(3) a third portion P3 (P3a, P3b, P3c, or P3d) covered with the first sealing layer 41.

In other words, the second portion P2 (P2a, P2b, P2c, or P2d) is a portion of the wire W exposed from the first sealing layer 41.

For comparison with the first embodiment described above, a form is assumed in which the sealing member 40 is constituted only of a hard first sealing layer 41 (hereinafter referred to as “Comparative Example 1”). The sealing member 40 of Comparative Example 1 does not include the second sealing layer 42. In Comparative Example 1, the wires W are covered entirely only with the first sealing layer 41.

When an abnormality such as a short circuit occurs in the respective semiconductor element 20 (the transistor 21 or the diode 22) in the semiconductor module 100, an abnormal state may occur in which an overcurrent is continuously supplied to the wire W. In Comparative Example 1, the entire wire W is firmly fixed by the hard first sealing layer 41. Therefore, even when the temperature rises in the abnormal state, the wire W is not cut off, resulting in continuous supply of the overcurrent. In order to solve this problem, in Comparative Example 1, it is necessary to externally connect a fuse to the semiconductor module 100.

In contrast to Comparative Example 1, in the first embodiment, the second portion P2 of the wire W is covered with the second sealing layer 42 that is softer than the first sealing layer 41. Therefore, when the temperature rises due to occurrence of an overcurrent in an abnormal state, the second portion P2 of the wire W locally melts and cuts off. The overcurrent is cut off by cutting off of the second portion P2. That is, the second portion P2 of the first embodiment functions as a fuse that is blown when an overcurrent occurs. As described above, according to the first embodiment, it is possible to provide the semiconductor module 100 incorporating a function of cutting off an overcurrent in an abnormal state (hereinafter referred to as a “current cut off function”).

It is to be noted that, in the first embodiment, since the current breaker function is incorporated in the semiconductor module 100, a configuration for externally connecting a fuse to the semiconductor module 100 is not necessary in principle. However, in addition to the current breaker function of the semiconductor module 100 itself, a fuse may be externally connected to the semiconductor module 100.

Next, for comparison with the first embodiment, a form is assumed in which the sealing member 40 includes only a soft second sealing layer 42 (hereinafter referred to as “Comparative Example 2”). The sealing member 40 of Comparative Example 2 does not include the first sealing layer 41. In Comparative Example 2, each wire W is entirely covered only with the second sealing layer 42.

When the temperature of the environment in which the semiconductor module 100 is used changes in a wide range from a high temperature to a low temperature, thermal stress due to the temperature change may act on the semiconductor unit 10. In Comparative Example 2, the semiconductor unit 10 is not sufficiently fixed by the sealing member 40, so that each part of the semiconductor unit 10 may be deformed due to thermal stress, and damage such as cracking due to deformation (warping) may occur. For example, it is assumed that damage due to thermal stress occurs in the bonding material 14 for bonding each semiconductor element 20 to the mounting substrate 12 or a portion where each semiconductor element 20 and the corresponding wire W are bonded. In the above description, there is assumed a deformation of each part resulting from thermal stress, but deformation resulting from factors other than thermal stress may also occur in the semiconductor module 100.

In contrast to Comparative Example 2, in the first embodiment, the semiconductor unit 10, and the first portion P1 and the third portion P3 of the wire W are firmly fixed by being covered with the hard first resin material. That is, deformation of each part of the semiconductor unit 10 due to thermal stress is suppressed. Therefore, according to the first embodiment, it is possible to suppress damage to each part due to thermal stress as compared with Comparative Example 2. As described above, according to the first embodiment, it is possible to provide the semiconductor module 100 incorporating the current breaker function while suppressing damage to each part of the semiconductor module 100.

In the first embodiment, the thickness T1 of the first sealing layer 41 is greater than the thickness T2 of the second sealing layer 42 (T1 > T2). Therefore, as compared with the configuration in which the thickness T1 of the first sealing layer 41 is less than the thickness T2 of the second sealing layer 42, the effect of suppressing damage to each part of the semiconductor module 100 by the first sealing layer 41 can be effectively secured.

FIG. 4 is a process chart illustrating a manufacturing process of the semiconductor module 100. First, the housing 30 to which the plurality of connection terminals 33 is fixed is prepared, and the semiconductor unit 10 is mounted in the housing 30 (step Q1). In step Q2 after step Q1, the wires W (Wa, Wb, and Wc) are formed by a known bonding process.

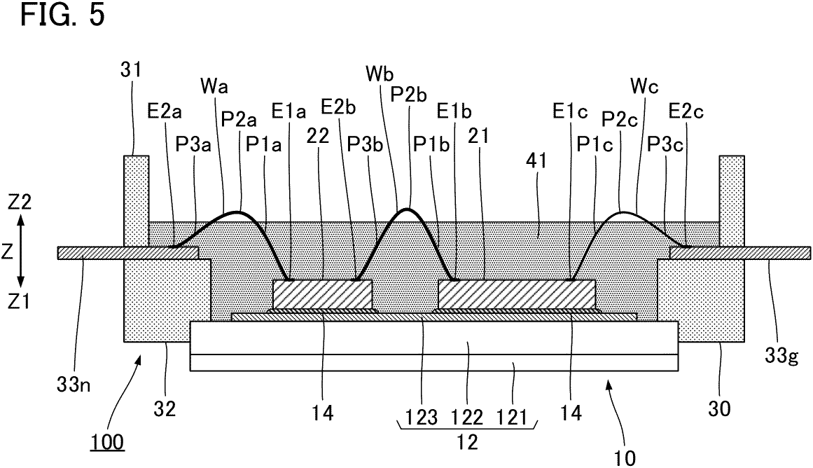

In step Q3 after step Q2, a liquid first resin material is filled into the space inside the housing 30, and the first resin material is then cured to form the first sealing layer 41 as illustrated in FIG. 5. The first resin material is a resin material such as an epoxy resin or an acrylic resin. In step Q3, the amount of the first resin material filled is adjusted such that the first portion P1 and the third portion P3 of the respective wire W are covered with the first sealing layer 41, and the second portion P2 of the wire W is exposed from the surface of the first sealing layer 41.

In step Q4 after step Q3, the liquid second resin material is filled into the space inside the housing 30, and the second resin material is then cured to form the second sealing layer 42. The second resin material is, for example, a silicone gel. In step Q3, the amount of the second resin material filled is adjusted such that the second portion P2 of each wire W is covered with the second sealing layer 42. The method of manufacturing the semiconductor module 100 is as described above.

### B: Second Embodiment

A second embodiment of the present disclosure will be described. It is to be noted that in the forms exemplified below, elements having the same functions as those of the first embodiment are denoted by the same reference signs as those in the description of the first embodiment, and detailed description thereof will be appropriately omitted.

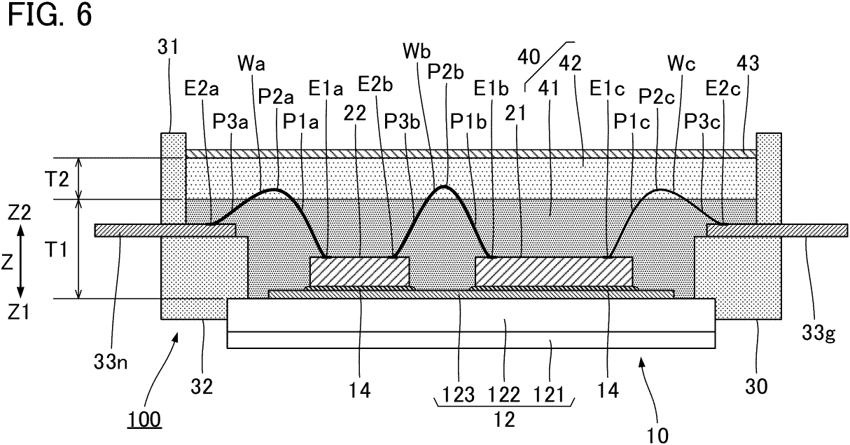

FIG. 6 is a cross-sectional view of a semiconductor module 100 according to a second embodiment. As illustrated in FIG. 6, the semiconductor module 100 of the second embodiment includes a protection member 43 in addition to the same elements (a semiconductor unit 10, a housing 30, and a sealing member 40) as those of the first embodiment.

The protection member 43 is an insulating plate-like member that covers a sealing member 40 (second sealing layer 42). That is, the second sealing layer 42 is interposed between a first sealing layer 41 and a protection member 43. Specifically, the protection member 43 covers the entire surface of the second sealing layer 42. That is, the protection member 43 overlaps the entire second sealing layer 42 in plan view from the Z axis direction. It is to be noted that the protection member 43 may be considered as an element of the sealing member 40. In other words, the sealing member 40 may comprise layers of the first sealing layer 41, the second sealing layer 42, and the protection member 43.

The protection member 43 is bonded to the sealing member 40 using, for example, the second sealing layer 42 as an adhesive. That is, the second sealing layer 42 is used not only for sealing the wire W but also for bonding the protection member 43. According to the above-described configuration, a special configuration for fixing the protection member 43 to the housing 30 is not necessary. However, the method of fixing the protection member 43 is not limited to the above-described example. For example, the protection member 43 may be bonded to the housing 30 or the sealing member 40 by a bonding material such as an adhesive.

The protection member 43 is harder than the second sealing layer 42. For example, the protection member 43 is formed from an insulating material such as mica. However, the material of the protection member 43 may be freely selected. For example, the protection member 43 may be formed from a resin material such as an epoxy resin or an acrylic resin. The thickness of the protection member 43 is less than the thickness T2 of the second sealing layer 42. However, there may also be assumed a configuration in which the thickness of the protection member 43 is greater than the thickness T2 of the second sealing layer 42.

Also, in the second embodiment, effects that are substantially the same as those of the first embodiment are achieved. In the second embodiment, the second sealing layer 42 is protected by the protection member 43. Therefore, for example, the probability that foreign matter, such as moisture or dust, will enter the second sealing layer 42 can be reduced.

### C: Modifications

Specific modifications added to each embodiment exemplified above will be exemplified below. Any two or more modes freely selected from the following examples may be appropriately combined as long as there is no conflict.

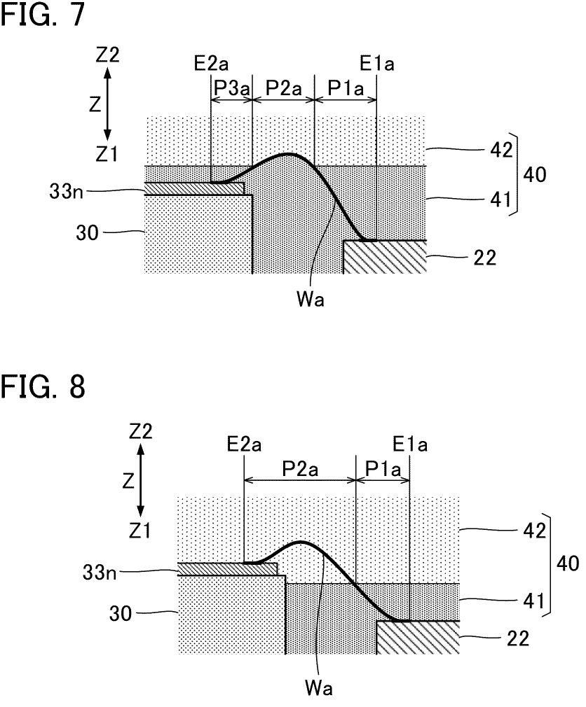

(1) In each of the above-described embodiments, as illustrated in FIG. 3, each of the second portions P2 is covered with the second sealing layer 42 over the entire circumference. However, in step Q3 of casting the liquid first resin material into the space inside the housing 30, the first resin material may actually come into contact with the lower surface of the second portion P2 due to the surface tension of the first resin material, as illustrated in FIG. 7.

Even with the configuration of FIG. 7, in an abnormal state, a portion of the second portion P2 covered with the second sealing layer 42 (the upper surface and the side surface) melts and cuts off, so that the current cut off function is nevertheless achieved. That is, in addition to the configuration of FIG. 3 in which the second portion P2 is covered with the second sealing layer 42 over the entire circumference, the configuration of FIG. 7 in which a part of the peripheral surface of the second portion P2 is covered with the second sealing layer 42 is also included in the scope of the present disclosure.

(2) In each of the above-described embodiments, connection terminals 33 that are covered with the first sealing layer 41 have been exemplified, but a configuration in which the connection terminals 33 are covered with the first sealing layer 41 is not essential. Specifically, as illustrated in FIG. 8, each connection terminal 33 may be covered with the second sealing layer 42. In the configuration of FIG. 8, the upper surface of the first sealing layer 41 is at a position lower than the connection terminal 33.

The third portions P3 (P3a, P3b, P3c, and P3d) in each of the above-described embodiments are portions covered with the first sealing layer 41. In the configuration of FIG. 8, a portion of each wire W other than the first portion P1 (P1a, P1b, P1c, or P1d) is the second portions P2 (P2a, P2b, P2c, or P2d) covered with the second sealing layer 42. That is, the third portion P3 may be omitted from each wire W.

In each of the above-described embodiments, the first portions P1 including the first ends E1 and the third portions P3 including the second ends E2 are covered with the first sealing layer 41. That is, both ends of the wires W are covered with the first sealing layer 41. Therefore, the above-described embodiments have an advantage that the bonding between each of the first ends E1 and the second ends E2 of the wires W and another element can be firmly maintained, in comparison with the configuration of FIG. 8.

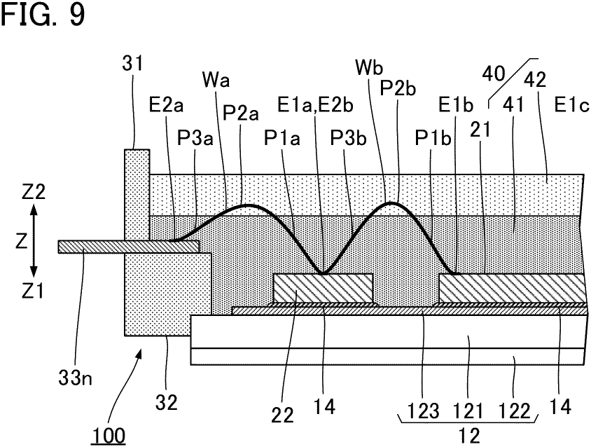

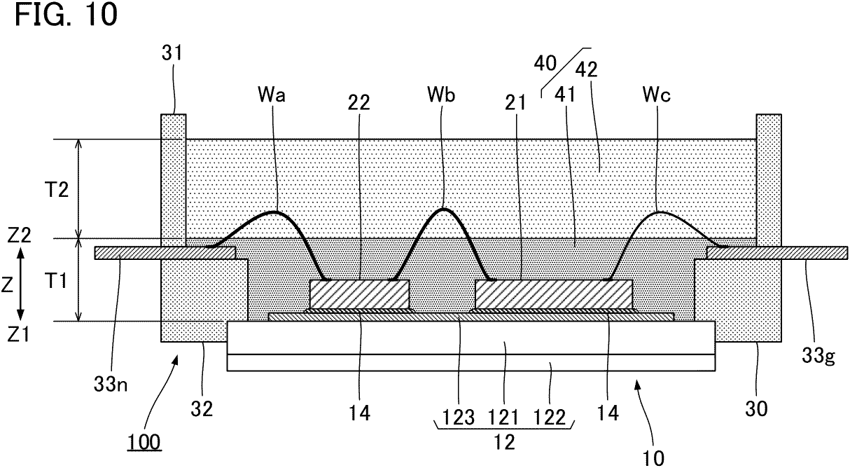

(3) In each of the above-described embodiments, a form in which the wires W are formed to be separate from each other has been exemplified, but the multiple wires W in each of the above-described embodiments may be continuously formed by, for example, stitch bonding. For example, as illustrated in FIG. 9, the wire Wa and the wire Wb may be continuously formed in a series of steps. The first end E1a of the wire Wa and the second end E2b of the wire Wb form one stitch. As will be understood from the above description, the “wiring member” in the present disclosure may be a part of conductors continuously formed with each other.

(4) In each of the above-described embodiments, a form in which the sealing member 40 includes two layers of the first sealing layer 41 and the second sealing layer 42 has been exemplified, but one or more other insulating layers may be interposed between the first sealing layer 41 and the second sealing layer 42. In addition, in each of the above-described embodiments, a form in which the second sealing layer 42 covers the entire surface of the first sealing layer 41 has been exemplified, but the second sealing layer 42 may cover a part of the first sealing layer 41. Similarly, the protection member 43 may cover only a part of the second sealing layer 42.

(5) In each of the above-described embodiments, the configuration in which the thickness T1 of the first sealing layer 41 is more than the thickness T2 of the second sealing layer 42 (T1 > T2) has been exemplified, but the relationship between the thickness T1 of the first sealing layer 41 and the thickness T2 of the second sealing layer 42 is not limited thereto. For example, as illustrated in FIG. 10, a configuration in which the thickness T1 of the first sealing layer 41 is less than the thickness T2 of the second sealing layer 42 (T1 < T2) is also assumed. It is to be noted that the protection member 43 of the second embodiment may be added to the configuration of FIG. 10. In addition, the thickness T1 of the first sealing layer 41 may be equal to the thickness T2 of the second sealing layer 42 (T1 = T2).

As described above, the first sealing layer 41 of the sealing member 40 achieves a function of suppressing deformation of each part of the semiconductor module 100 resulting from, for example, thermal stress (hereinafter referred to as “deformation suppressing function”). On the other hand, the second sealing layer 42 of the sealing member 40 acts such that the second portions P2 of the wire or wires W exhibit a current cut off function (i.e., function as a fuse). The relationship between the thickness T1 of the first sealing layer 41 and the thickness T2 of the second sealing layer 42 is set according to the relationship between the deformation suppressing function and the current breaker function required for the semiconductor module 100.

For example, in a configuration in which the deformation suppressing function is regarded as important, a form in which the thickness T1 of the first sealing layer 41 is greater than the thickness T2 of the second sealing layer 42 (T1 > T2), as the first embodiment or the second embodiment, is preferable. According to the above-described form, deformation of the semiconductor module 100 resulting from thermal stress or the like can be effectively suppressed as compared with a configuration in which the thickness T1 is less than the thickness T2. On the other hand, in a configuration in which the current breaker function is regarded as important, a form in which the thickness T1 of the first sealing layer 41 is less than the thickness T2 of the second sealing layer 42 (T1 < T2), as illustrated in FIG. 10, is preferable. According to the above-described configuration, a sufficient length of the second portions P2 is secured in the wires W. Therefore, as compared with the configuration in which the thickness T1 is greater than the thickness T2, the form has an advantage in that the second portions P2 easily melt and cut off when an overcurrent occurs.

The relationship between the deformation suppressing function and the breaker cutoff function depends also on, for example, the structure of the mounting substrate 12. For example, a form in which the mounting substrate 12 includes a DCB substrate (hereinafter referred to as “form A”) has a tendency that, even with the first sealing layer 41 being thin, deformation of each part resulting from thermal stress or the like is less likely to occur. Therefore, in form A, in addition to the configuration in which the thickness T1 of the first sealing layer 41 is greater than the thickness T2 of the second sealing layer 42 (T1 > T2), a configuration in which the thickness T1 is equal to the thickness T2 (T1 = T2) or a configuration in which the thickness T1 is less than the thickness T2 (T1 < T2) may be adopted. As the thickness T2 of the second sealing layer 42 is greater, the second portions P2 are more easily melt and cut off when an overcurrent occurs.

On the other hand, in a form in which the mounting substrate 12 includes, for example, an AMB substrate or an IMS (hereinafter referred to as “form B”), in order to appropriately secure both the deformation suppressing function and the current breaker function, it is important that the first sealing layer 41 be thin. Therefore, in form B, a configuration in which the thickness T1 of the first sealing layer 41 is less than the thickness T2 of the second sealing layer 42 (T1 < T2) as illustrated in FIG. 10 is preferable.

(6) Each of the wires W in each of the above-described embodiments may be replaced with a flexible ribbon cable (flat cable) or a plate-like lead frame. That is, the wire W, the ribbon cable, and the lead frame in each of the above-described embodiments are comprehensively expressed as a wiring member electrically connected to the semiconductor element 20.

The “electrical connection” between an element A and an element B includes not only a state in which the element A and the element B are directly connected, but also a state in which the element A and the element B are indirectly connected via another conductor. For example, the wires Wd and each semiconductor element 20 in each of the above-described embodiments are indirectly connected via the conductor pattern 123. Consequently, the wires Wd are electrically connected to each semiconductor element 20.

(7) The transistor 21 in the semiconductor unit 10 is not limited to the IGBT exemplified in each of the above-described embodiments. For example, a metal-oxide-semiconductor field-effect transistor (MOSFET) may be used as the transistor 21. In the form using a MOSFET, the electrode 21c is one of the source electrode and the drain electrode, and the electrode 21e is the other of the source electrode and the drain electrode. In addition, a reverse conducting IGBT (RC-IGBT) including an IGBT and a freewheeling diode (FWD) may be used as the semiconductor element 20. That is, the diode 22 in each of the above-described embodiments may be omitted. As will be understood from the above description, the number of semiconductor elements 20 in the semiconductor unit 10 is freely selectable.

(8) In each of the above-described embodiments, a form in which the transistor 21 and the diode 22 are mounted on the mounting substrate 12 has been exemplified, but the plurality of semiconductor elements 20 mounted on the mounting substrate 12 may be of the same type or of different types. For example, multiple transistors 21 may be mounted on the mounting substrate 12.

(9) In each of the above-described embodiments, the semiconductor module 100 in which the control voltage is supplied from the external control device to the connection terminal 33g has been exemplified, but the present disclosure may be similarly applied to an intelligent power module (IPM) in which a control device that supplies the control voltage to the control electrode 21g of the transistor 21 is built in the semiconductor module 100.

(10) The statement of “n-th” (n is a natural number) in the present application is used only as a formal and convenient sign (label) for distinguishing each element in notation, and does not have any substantive meaning. Therefore, the position, the order of manufacture, or the like of each element cannot be restrictively interpreted based on the notation “n-th”.

### DESCRIPTION OF REFERENCE SIGNS

100 semiconductor module
10 semiconductor unit
12 mounting substrate
121 insulating plate
122 metal plate
123 conductor pattern
20 semiconductor element
21 transistor
22 diode
30 housing
31 side wall
32 projection
33 (33p, 33n, 33g) connection terminal
40 sealing member
41 first sealing layer
42 second sealing layer
43 protection member

What is claimed is:

1. A semiconductor module comprising:
a mounting substrate;
a semiconductor element mounted on the mounting substrate;
a housing configured to house the semiconductor element;
a first sealing layer filled in a space inside the housing to seal the semiconductor element;
a second sealing layer of a resin material softer than the first sealing layer and layered on the first sealing layer; and
a wiring member electrically connected to the semiconductor element,
wherein the wiring member includes:
a first portion covered with the first sealing layer; and
a second portion covered with the second sealing layer.

2. The semiconductor module according to claim 1, further comprising a connection terminal mounted to the housing,
wherein the wiring member includes a first wiring member that electrically connects the semiconductor element and the connection terminal.

3. The semiconductor module according to claim 1, wherein:
the semiconductor element includes a first semiconductor element and a second semiconductor element, and
the wiring member includes a second wiring member configured to electrically connect the first semiconductor element and the second semiconductor element.

4. The semiconductor module according to claim 1, wherein:
the wiring member with a first end and a second end opposite to the first end includes:
the first portion and the second portion; and
a third portion,
the first portion includes the first end of the wiring member,
the third portion includes the second end of the wiring member,
the second portion is a portion between the first portion and the third portion,
the first portion and the third portion are covered with the first sealing layer, and
the second portion is covered with the second sealing layer.

5. The semiconductor module according to claim 1, wherein a thickness of the first sealing layer is greater than a thickness of the second sealing layer.

6. The semiconductor module according to claim 1, wherein a thickness of the first sealing layer is less than a thickness of the second sealing layer.

7. The semiconductor module according to claim 1, further comprising an insulating protection member configured to cover the second sealing layer.
